(19) United States
(12) Patent Application Publication
(10) Pub. No.: US 2004/0056258 A1
(43) Pub. Date: Mar. 25, 2004

(54) Multi-wavelength luminous element

(76) Inventors: Kazuyuki Tadatomo, Itami-shi Hyogo (JP); Hiroaki Okagawa, Itami-shi Hyogo (JP); Yoichiro Ouchi, Itami-shi Hyogo (JP); Takashi Tsunekawa, Itami-shi Hyogo (JP)

Correspondence Address: WENDEROTH, LIND & PONACK, L.L.P., 2033 K STREET N. W., SUITE 800, WASHINGTON, DC, 20006-1021, US

(21) Appl. No.: 10/450,116

(22) PCT Filed: Dec. 10, 2001
(86) PCT No.: PCT/JP01/10769

(30) Foreign Application Priority Data
Dec. 11, 2000 (JP) 2000-375326

(51) Int. Cl. H01L 27/15; H01L 31/12; H01L 33/00

(52) U.S. Cl. 257/79

(57) ABSTRACT

As an embodiment of the element structure, a structure including, from the downside, a sapphire C-plane substrate 1, a GaN buffer layer 11 grown at a low temperature, an un-doped GaN layer 12, an Si-doped n-GaN contact layer 21, a light emitting layer 3 of a multiple quantum well structure (MQW) having plural well layers, an Mg-doped p-AlGaN cladding layer 22, and an Mg-doped p-GaN contact layer 23 is mentioned. The above-mentioned light emitting layer 3 is capable of multi-wavelength light emission by a multi-layer structure emitting light having at least two peaks in an emission spectrum, which is achieved by, for example, forming plural groups having different band gaps of the well layer. As a result, a light having plural wavelengths is emitted from a single light emitting layer, and by simply injecting current into a pair of p-type and n-type electrodes, a light emitting element emitting multicolor light, particularly white light, can be provided.

### TECHNICAL FIELD

The present invention relates to a compound semiconductor element, particularly a light emitting element.

### BACKGROUND ART

A white light emitting LED comprising a combination of a blue-LED and a fluorescent material that emits yellow fluorescence upon excitation by the blue light emitted by said LED has been developed and put to practical use. A white light source using such LED (solid light-emitting-element) is expected to be a light source for new illumination of the next generation. Other than this, such white light source has been further realized by a combination of an ultraviolet-LED and a fluorescent material that converts ultraviolet light to a multi-wavelength light, a method of further combining a plural color visible-LED of blue, green, red etc., and the like.

However, the method using an ultraviolet-LED is considered to have a limited efficiency of energy use, because ultraviolet light emitted by injection of high energy carrier is converted to a low energy visible light, thus creating a great energy loss by the wavelength conversion. This problem is also found in the use of a blue-LED and a fluorescent material in combination. In contrast, the method of producing a white light based on complementary color by the use of a plural color visible-LED is free of wavelength conversion and thus advantageously superior in the efficiency of energy use. On the other hand, it contains many problems in that its multiple point light source causes poor mixing of lights, drive voltage that varies depending on the wavelengths of the emitted light renders drive circuit complicated, color tone changes with time due to the variation in degradation mode depending on the wavelengths of the emitted light, and the like.

In view of the above-mentioned problems, the present inventors have attempted to develop a multi-wavelength light emitting element having a high efficiency of energy use due to direct light conversion, which is free of a wavelength conversion step using a fluorescent material and the like, and completed the present invention.

There have been revised and developed various LEDs emitting multi-wavelength light from a single chip. However, most of them are laminated as different light emitting layers according to the wavelength of the emitted light, and have a structure wherein an n-type semiconductor layer and a p-type semiconductor layer are disposed on both sides of each light emitting layer. This in turn necessitates at least one extraction electrode for each light emitting layer, leaving the problems of complicated drive circuit, changes in color tone due to different degradation modes and the like yet to be resolved.

### DISCLOSURE OF THE INVENTION

The present invention aims at providing a light emitting element based on a new concept wherein light having multiple wavelengths is emitted from a single light emitting layer, and multicolor light is emitted upon mere injection of a current into a pair of p-type and n-type electrodes, unlike the above-mentioned conventional concept. Inasmuch as only one light emitting layer is used, the provided white light source is free of changes in color tone due to different degradation modes, is superior in mixing of wavelengths, has a simplified drive circuit and is easy to handle.

In an attempt to solve the above-mentioned problems of conventional white light sources comprising (1) a combination of an ultraviolet-LED or a blue-LED and a fluorescent material, (2) a combination of plural color visible-LED, (3) the use of conventional multicolor light emitting chip, a new element structure that affords multicolor light emission from a single light emitting layer has been developed.

The multi-wavelength light emitting element of the present invention is a light emitting element having an n-type semiconductor layer, a p-type semiconductor layer and a light emitting layer having a multi-layer structure, which is characterized in that the light emitting layer comprises a multi-layer structure emitting a light having at least two peaks in an emission spectrum.

The above-mentioned light emitting layer preferably comprises a multiple quantum well structure, in which case, multi-wavelengths can be achieved by disposing, in the multiple quantum well structure, at least two quantum well layers having different wavelength of emitting light as achieved by varying one or more of a band gap, a well layer width, an amount or kind of doping, and strength of piezo electric field.

### BRIEF DESCRIPTION OF THE DRAWINGS

FIG. 1 is a cross section of the multi-wavelength light emitting element of the present invention.

FIG. 2 is a schematic drawing of the band structure of a light emitting layer of the three-wavelength light emitting element of the present invention.

FIG. 3 is a schematic drawing of the band structure of a light emitting layer of the two-wavelength light emitting element of the present invention.

In each drawing, 1 is a substrate, 21 is an n-GaN contact layer, 22 is a p-AlGaN cladding layer, 23 is a P-GaN contact layer, 3 is a light emitting layer, 31a, 31b and 31c are well layers, and 32a, 32b and 32c are barrier layers.

### DETAILED DESCRIPTION OF THE INVENTION

In general, a multiple quantum well structure used as a light emitting layer in a light emitting element has a structure wherein plural well layers having almost the same properties (band gap etc.) are disposed for increased emission efficiency. That is, in a multiple quantum well layer of barrier layer/well layer/barrier layer/well layer/ . . . /barrier layer, the well layers have the same structure (composition, band gap, well width) and the barrier layers, too, often have the same composition (band gap) except the layers on both ends, though the width may be modulated.

In contrast, the element structure developed by the present inventors is characterized in that the composition (band gap) and width of well layers and/or barrier layers forming the multiple quantum well structure in a single light emitting layer are modulated, and emission of multicolor light, particularly white light, can be achieved at high efficiency from a single light emitting layer. In other words, two or more kinds of pairs of a well layer and a barrier layer having different properties are mixed in a layer recognized as a single light emitting layer in a conventional light emitting element structure, thereby achieving emission of light having a different wavelength for each pair, whereby a light emitting element having at least two emission peaks in an emission spectrum is constituted. Because this constitution is based on a direct light conversion method, free of a fluorescent material, it shows fine efficiency of energy use, and because the light emitting layer is apparently a single layer, the element structure is not complicated.

The embodiment of the present invention is explained in the following based on the drawings.

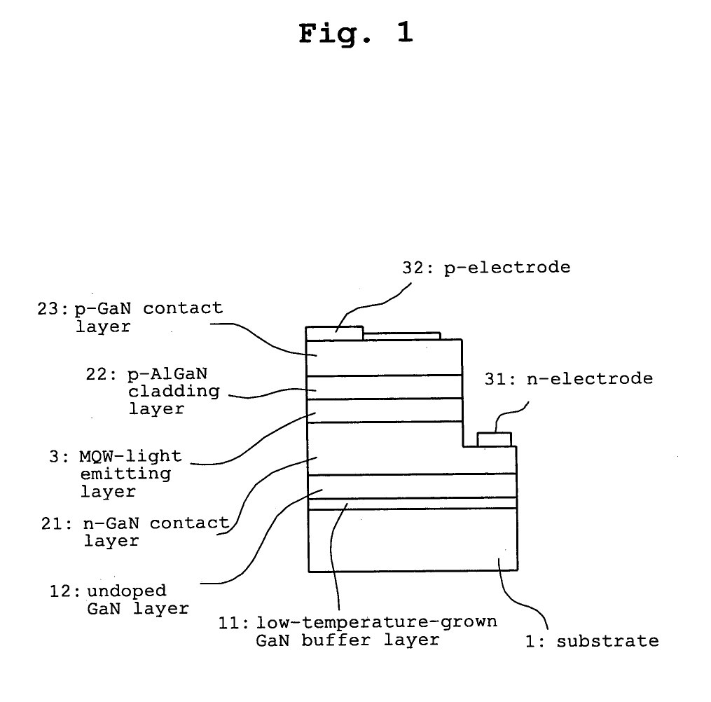

FIG. 1 shows one example of the compound semiconductor light emitting element of the present invention, which comprises, from the downside, a sapphire C-plane substrate 1, a GaN buffer layer 11 grown at a low temperature, an un-doped GaN layer 12, an Si-doped n-GaN contact layer 21, a light emitting layer 3 having a multiple quantum well structure (MQW) comprising multiple well layers,.an Mg-doped p-AlGaN cladding layer 22, and an Mg-doped p-GaN contact layer 23, wherein the exposed part of the n-GaN contact layer 21 has an n-electrode 31 and a p-electrode 32 on a surface of the p-GaN contact layer 23. The present invention is characterized in that it has a multi-layer structure such that the light emitted from the above-mentioned light emitting layer 3 has at least two peaks in an emission spectrum. As used herein, by the peak is meant a steep peak as well as a broad peak, also encompassing an apparent single peak formed by two overlapping broad peaks.

As mentioned above, the light emitting layer 3 has a multi-layer structure affording at least two peaks in an emission spectrum. This multi-layer structure is typically a multiple quantum well structure. Such multiple quantum well structure comprises laminates of plural pairs, wherein one pair consists of a well layer and a barrier layer. In the present invention, the aforementioned laminated pairs are divided into sections in the number corresponding to the number of peak lights desired to be generated (namely, into three groups in the case of a three-wavelength light emitting element). Each group has parameters (e.g., band gap, well layer width, amount or kind of doping, and strength of piezo electric field) that are different from those of other groups in one or more of the parameters, whereby the light having plural emission wavelengths is generated.

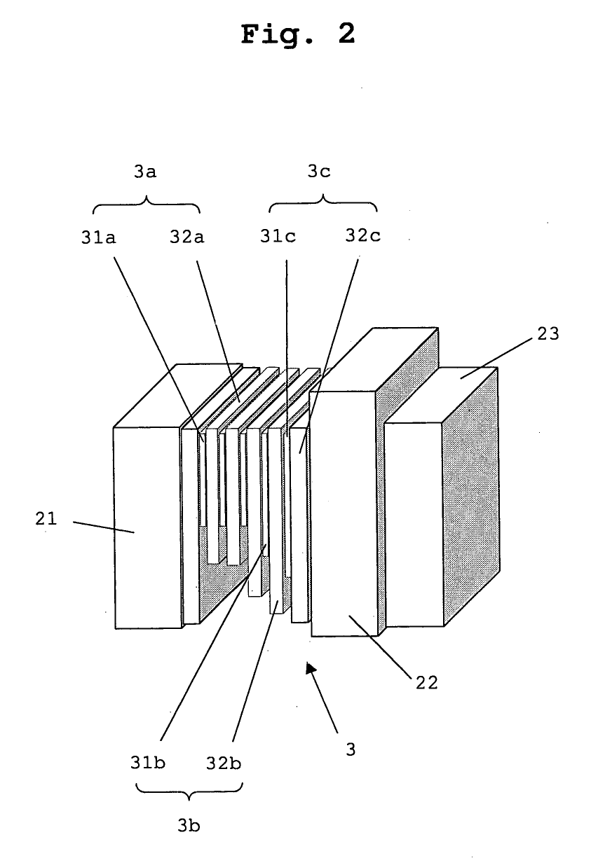

FIG. 2 shows an embodiment wherein, of the above-mentioned parameters, each section has a different band gap, and the band structure of the light emitting layer 3 of a three-wavelength light emitting element is schematically shown. The light emitting layer 3 consists of a first group 3a, a second group 3b and a third group 3c, which are sectioned by varying the band gap of a well layer and all consist of an un-doped InGaN. To be specific, the light emitting layer 3 consists of, from the n-GaN contact layer 21 side, the first group 3a comprising three well layers 31a emitting amber at about 600 nm and barrier layers 32a sandwiched therebetween, the second group 3b comprising one well layer 31b emitting green at about 535 nm and an adjacent barrier layer 32b, and the third group 3c comprising one well layer 31c emitting blue at about 470 nm and an adjacent barrier layer 32c.

In the case of this material system, the mean free path of the positive holes injected into the active layer is said to be several dozen nm, and for efficient injection and diffusion of positive holes in a multiple quantum well layer and for well-balanced emission of multicolor light, the layer structure is the key. In the embodiment of FIG. 2, electrons are considered to diffuse uniformly, wherein the balance of wavelengths of the emitted lights are mostly determined by the distribution of positive holes. Accordingly, while the third group 3c emitting blue light is disposed on the p-AlGaN cladding layer 22 side, which supplies positive holes, the well layer 31c was made to be a single layer in view of the high density of the positive holes. Then the second group 3b emitting green light is disposed in the middle position. It is sufficient that the well layer 31b be a single layer, because spectral luminous efficacy of green is high, though the positive hole density decreases somewhat. Lastly, the first group emitting amber light is disposed on the n-GaN contact layer 21 side. The well layer 31a is a three-layer constitution because the positive hole density decreases and luminous efficacy also decreases.

For easy diffusion of the positive holes, the band gap of barrier layers 32a, 32b and 32c is reduced from the p-AlGaN cladding layer 22 side, which is a positive hole supply side. According to the design, EB<EWL+0.8, except the both sides of the barrier layer, wherein the band gap of the barrier layer is EB [eV], and a greater band gap of a well layer adjacent to a barrier layer is EWL [eV]. Linking the band gap of the barrier layer to that of the well layer in this way is convenient, because it gives a potential field to positive holes extremely difficult to move.

The multicolor light emitting element thus prepared has three peak wavelengths of approximately at 600 nm, 535 nm and 470 nm of the light emitted from each group, and by interference of these emitted lights with each other renders the output light a white light. Such white light source was processed to give a lamp and emission output was measured. As a result, the output was 20 mW (20 mA power distribution) and the drive voltage was 3.6 V (average), which was the same as with a blue-LED.

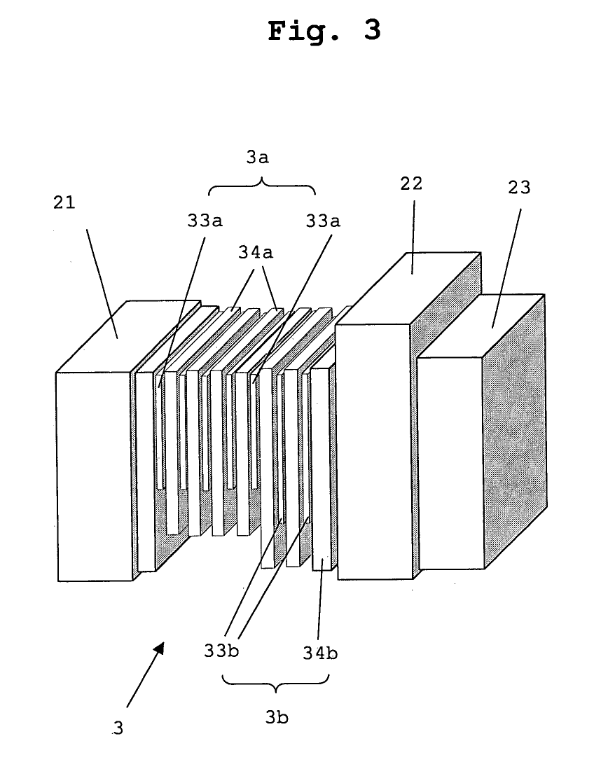

FIG. 3 shows an embodiment wherein each group similarly has a different band gap, and schematically shows the band structure of the light emitting layer 3 of a two-wavelength light emitting element. The light-emitting layer 3 has been divided into two sections by changing the band gap of the well layers; i.e., the first group 3a and the second group 3b, and as in the embodiment of FIG. 2, both are made of an un-doped InGaN. In the embodiment of FIG. 3, too, the electron is considered to be uniformly diffused, wherein the balance of wavelengths of the emitting lights are mostly determined by the distribution of positive holes. In this case, the second group 3b consisting of two well layers 33b emitting blue at about 475 nm and a barrier layer 34b is disposed on the p-AlGaN cladding layer 22 side, i.e., positive hole injection side, and the first group 3a consisting of five well layers 33a emitting yellow at about 575 nm and a barrier layer 34a is disposed on the n-GaN contact layer 21 side. This is in consideration of predictable decrease in the positive hole density and spectral luminous efficacy. In addition, for easy diffusion of positive holes, the band gap of the barrier layers 34a, 34b has been made to also decrease from the p-AlGaN cladding layer 22 side.

The multicolor light emitting element thus prepared is a white light source having two peak wavelengths approximately at 575 nm and 475 nm. The white light source was processed to give a lamp and emission output was measured. As a result, the output was 25 mW (20 mA power distribution) and the drive voltage was 3.6 V (average), which was the same as with a blue-LED.

When the above-mentioned two kinds of white light sources are compared, the output was higher in the latter two-wavelength light emission, but when compared in terms of the average color rendering index, the light source of the former was Ra=92, the latter showed as low as Ra=77. For a light source having a high average color rendering index, it is important to increase the kind of the well layer corresponding to the wavelength of the emitted light.

The conditions to make the emitted output of the multicolor light emitting element of the present invention beyond a certain level was examined in detail and the results are explained referring to FIG. 2. The conditions to make the emitted output beyond a certain level were

(i) EB(n)<EW(n) and EB(n+1)<EW(n), and

(ii) the primary function approximation of EW(n) as to n and that of EB(m) as to m have a negative gradient,

wherein the well layers were numbered (n) from the p-AlGaN side, and the band gap thereof was taken as EW(n) (conveniently defined by EW [eV]=1.2398/λp from the wavelength of emitted light (λp [μm])) and the p-GaN side barrier layers were numbered (m) in the same manner from the end layer thereof and the band gap thereof was taken as EB(m) (calculated by EB [eV]=3.39−2.50 X+X² wherein X is an InN crystal mixing ratio and set value).

While the embodiment of a sapphire C-plane substrate is shown here, sapphire A-plane (R-plane), SiC (6H, 4H, 3C), GaN, AlN, Si, spinel, ZnO, GaAs, NGO and the like can be used besides this, and other materials may be further used as long as the object of the invention can be met. The planar orientation of the substrate is not particularly limited, and it may be a just substrate or an off-angled substrate. In addition, a substrate wherein a several μm GaN-based semiconductor is epitaxially grown on a sapphire substrate and the like may be used.

As a conductive layer grown on a substrate, the embodiments of GaN, InGaN, AlGaN are shown in FIG. 1. To achieve the object, a suitable layer structure generalized by Al_{y}InₓGa_{1-x-y}N (0≦x≦1, 0≦y≦1, 0≦x+y≦1) and defined by the composition ratios of x and y can be selected.

While a preferable example of the location of the well layer is shown here, the heat resistance of InGaN having a high InN crystal mixing ratio may become a problem. Though greatly dependent on the crystal growth apparatus, it takes several hours to complete growing an n-GaN contact layer 21, then lowering the temperature to 700° C. to grow an In_{0.8}Ga_{0.2}N well layer, and growing a p-GaN contact layer 23. Most of the time is consumed for the growth of a light emitting layer. Some crystal growth apparatuses suffer from the damage by heating during this process, resulting in an emission output that does not increase.

This case can be solved by forming films from the shorter wavelength side and finally laminating InGaN having a high InN crystal mixing ratio. As a result, a multi-wavelength light emitting element having a well layer emitting shorter wavelength light disposed on the side to supply electron (n-type semiconductor layer side) can be realized. Namely, when the above-mentioned problem of the damage by heat in the embodiment of a multi-wavelength light emitting element shown in FIG. 2 is considered to be important, the quantum well part of the third group 3c emitting blue light at the shortest wavelength of 470 nm is disposed adjacent to the n-GaN contact layer 21, which is an electron supply side, and the first group 3a emitting amber light at the longest wavelength of 600 nm is disposed on the p-AlGaN cladding layer 22 side. In the embodiment shown in FIG. 3, too, the positions of the first group 3a and the second group 3b only need to be exchanged.

In the embodiments explained above, the wavelength of the emitted light was changed by changing the band gap by mainly varying the composition of the well layer. Other than this embodiment, for example, an embodiment involving change in one or more items of the well layer width, the amount and kind of doping, strength of the piezo electric field and the like can be employed.

When the width of the well layer is changed, there are found an effect provided by the change of effective band gap due to the quantum effect, resulting in change in the wavelength of the emitted light, and an effect provided by the change of effective band gap due to the gradient of the band structure because of the piezo electric field. When the width of the well layer is increased, the effect of the piezo electric field is enhanced, which causes shift of the wavelength of the emitted light to a longer wavelength, thereby producing a different wavelength of emitted light. For example, emission of about 475 nm blue light and about 575 nm yellow light can be achieved by setting the width of the well layer to 2.5 nm and 7.5 nm, respectively.

In addition, by positively utilizing the light emission related to the deep level generated by intentionally doped impurity, the amount and kind of the material doped in the well layer can be controlled, thereby producing a different wavelength of emitted light. For example, addition of Zn or Zn and Si into a particular well layer affords control of the wavelength of the emitted light.

The strength of the piezo electric field can be controlled by controlling the stress applied to the well layer by the design of the layer structure, and the wavelength of the emitted light can be varied by changing the effective band gap. For example, the composition of the barrier layers sandwiching the well layer is changed to reduce the lattice constant, which is specifically achieved by adding Al to the barrier layer as a semiconductor composition component. As a result, compression strain is applied to the well layer to also change the effective band gap, which in turn changes the wavelength of the emitted light to a longer wavelength. In this way, by controlling the composition of the barrier layer or cladding layer in the light emitting layer, thickness of the base layer, substrate and the like and by changing the stress, the wavelength of the emitted light can be controlled.

### EXAMPLES

### Example 1

An element having a sectional structure shown in FIG. 1, which is one example of the multi-wavelength light emitting element of the present invention, was prepared as in the following. A 500 μm-thick sapphire C-plane substrate was used and a conventional normal pressure MOVPE (metalorganic vapor phase epitaxy) was used as a crystal growth apparatus. The sapphire substrate was set in the MOVPE apparatus, and the temperature was raised to 1100° C. in a hydrogen rich stream. After maintaining for a predetermined time for thermal etching, the temperature was lowered to 450° C. to grow about 20 nm of a low-temperature-grown GaN buffer layer. Subsequently, the temperature was raised to 1000° C., a 1000 nm un-doped GaN was grown and a 3000 nm n-GaN layer (Si-doped) was grown. After lowering to 700° C., 10 nm of a first In_{0.05}Ga_{0.95}N barrier layer (m=6) was grown, three In_{0.76}Ga_{0.24}N (2.5 nm thick) layers, two In_{0.35}Ga_{0.65}N (6 nm thick) barrier layers and an In_{0.2}Ga_{0.8}N (m=3, 6 nm thick) barrier layer were grown, and further, a second In_{0.55}Ga_{0.45}N (2.5 nm thick) well layer, a second In_{0.1}Ga_{0.9}N (6 nm thick) barrier layer, a first In_{0.35}Ga_{0.75}N (2.5 nm thick) well layers and a first In_{0.05}Ga_{0.95}N (10 nm thick) barrier layer were grown to give a light emitting layer. For the composition, the values estimated according to Eg [eV]=3.39−2.50X+X⁻² using the band gap values calculated from the aforementioned wavelengths of the emitted lights were used. After the completion of growth of the light emitting layer, the temperature was again raised to 1000° C. and an Mg-added 50 nm Al_{0.2}Ga_{0.8}N cladding layer was grown, and a 100 nm GaN contact layer similarly added with Mg was further grown. After the completion of the crystal growth, when the temperature lowered to 850° C., ammonia gas and hydrogen gas were changed to nitrogen gas flow, and the temperature was lowered to near room temperature. The substrate was taken out from an MOVPE furnace, subjected to etching processing, formation of electrodes and the like using conventional photolithography, electron-beam evaporation, reactive ion etching (RIE) and the like, and finally processed and diced to give-LED chips.

The obtained LED chips were processed using an epoxy resin to give an LED lamp, which was measured/evaluated for light emitting performance. A white light source emitting light having three wavelength peaks at approximately 600 nm, 535 nm and 470 nm was obtained, wherein the emission output was 20 mW (20 mA power distribution) and the drive voltage was the same as that of a blue-LED and 3.6 V (average). A lamp almost twice brighter than a white light source using a conventional fluorescent material was obtained. The average color rendering index was Ra=92.

### Example 2

In the same manner as in embodiment 1, a multicolor light emitting element was prepared. For forming a light emitting layer, an n-GaN layer (Si-doped) was grown, the temperature was lowered to 700° C., 10 nm of an In_{0.05}Ga_{0.95}N barrier layer (m=8) was grown on the n side, five In_{0.68}Ga_{0.32}N layers (2.5 nm thick) and four In_{0.3}Ga_{0.7}N barrier layers (6 nm thick) and a third In_{0.1}Ga_{0.9}N barrier layer (6 nm thick) were grown, and further, a second In_{0.35}Ga_{0.65}N well layer (2.5 nm thick), a second In_{0.1}Ga_{0.9}N barrier layer (6 nm thick), a first In_{0.35}Ga_{0.75}N well layer (2.5 nm thick) and a first In_{0.05}Ga_{0.95}N barrier layer (10 nm thick) were grown.

The obtained LED chip was processed using an epoxy resin to give an LED lamp, which was measured/evaluated for light emitting performance. A white light source emitting light having two wavelength peaks at approximately 575 nm and 470 nm in the emission spectrum was obtained, wherein the emission output was 25 mW (20 mA power distribution) and the drive voltage was the same as that of a blue-LED and 3.6 V (average). A lamp almost more than twice brighter than a white light source using a conventional fluorescent material was obtained. The average color rendering index was Ra=77.

Industrial Applicability

The multi-wavelength light emitting element of the present invention as explained above can be preferably used as a white light source for an LED. When compared to a conventional method,.the efficiency of energy use is fine because direct light conversion method is employed, without using a fluorescent material, and the light emitting layer, which is apparently a single layer, doe not make the element structure complicated. Therefore, the drive circuit can be simplified and has high efficiency, and because it is a single light emitting layer, a white light source free of change in color tone caused by different degradation modes, which is superior in mixing of wavelengths, can be realized.

This application is based on a patent application No. 375326/2000 filed in Japan, the contents of which are hereby incorporated by reference.

What is claimed is

1. In light emitting elements comprising an n-type semiconductor layer, a p-type semiconductor layer and a light emitting layer comprising a multi-layer structure, a multi-wavelength light emitting element comprising, in the light emitting layer, a multi-layer structure that emits light having at least two peaks in an emission spectrum.

2. The multi-wavelength light emitting element of claim 1, wherein the light emitting layer comprises a multiple quantum well structure having plural well layers.

3. The multi-wavelength light emitting element of claim 2, wherein the multiple quantum well structure comprises at least two quantum well layers having different wavelengths of emitted light, wherein the wavelengths have been changed by varying one or more items of a band gap, a well layer width, an amount or kind of doping, and strength of piezo electric field.

4. The multi-wavelength light emitting element of claim 2, wherein the multiple quantum well structure comprises at least one well layer having a wavelength of emitted light of less than 520 nm and at least one well layer having a wavelength of emitted light of not less than 520 nm.

5. The multi-wavelength light emitting element of claim 4, wherein a group of well layer(s) having a wavelength of the emitted light of less than 520 nm is group A and a group of well layer(s) having a wavelength of not less than 520 nm is group B, and wherein a well layer belonging to group A is disposed on a positive hole supply side.

6. The multi-wavelength light emitting element of claim 4, wherein a group of well layer(s) having a wavelength of the emitted light of less than 520 nm is group A and a group of well layer(s) having a wavelength of not less than 520 nm is group B, and wherein a well layer belonging to group A is disposed on an electron supply side.

7. The multi-wavelength light emitting element of claim 2, wherein the multiple quantum well structure comprises at least one well layer having a wavelength of emitted light of less than 500 nm, at least one well layer having a wavelength of emitted light of not less than 500 nm and less than 550 nm and at least one well layer having a wavelength of emitted light of not less than 550 nm.

8. The multi-wavelength light emitting element of claim 7, wherein a group of well layer(s) having a wavelength of the emitted light of less than 500 nm is group A, a group of well layer(s) having a wavelength of not less than 500 nm and less than 550 nm is group B and a group of well layer(s) having a wavelength of not less than 550 nm is group C, and wherein group A is disposed on a positive hole supply side, group C is disposed on an electron supply side and group B is disposed in between them.

9. The multi-wavelength light emitting element of claim 7, wherein a group of well layer(s) having a wavelength of the emitted light of less than 500 nm is group A, a group of well layer(s) having a wavelength of not less than 500 nm and less than 550 nm is group B and a group of well layer(s) having a wavelength of not less than 550 nm is group C, and wherein group A is disposed on an electron supply side, group C is disposed on a positive hole supply side and group B is disposed in between them.

10. The multi-wavelength light emitting element of claim 4 or 7, wherein the band gaps of the well layers are constituted to decrease from the positive hole supply side to the electron supply side.

11. The multi-wavelength light emitting element of claim 4 or 7, satisfying EB<EWL+0.8 [eV], wherein a greater band gap of a well layer adjacent to a barrier layer is EWL [eV], and the band gap of the barrier layer is EB [eV].

12. The multi-wavelength light emitting element of claim 4 or 7, wherein a barrier layer adjacent to a well layer emitting light having a shorter wavelength has a greater width than that of a barrier layer adjacent to a well layer emitting light having a longer wavelength.

13. The multi-wavelength light emitting element of claim 1, wherein at least the n-type semiconductor layer, the p-type semiconductor layer and the light emitting layer are made from a material defined by Al_{y}InₓGa_{1-x-y}N (0≦x≦1, 0≦y≦1, 0≦x+y≦1).

14. The multi-wavelength light emitting element of claim 1, wherein the wavelengths of two or more peaks contained in the emission spectrum are determined such that the light emitted from the multi-wavelength light emitting element is white.
